(19) United States
(12) Patent Application Publication
(10) Pub. No.: US 2025/0220821 A1
(43) Pub. Date: Jul. 3, 2025

(54) Scalable Fabrication of Microdevices From Metals, Ceramics, and Polymers

(71) Applicant: Carnegie Mellon University, Pittsburgh, PA (US)

(72) Inventors: O. Burak Ozdoganlar, Sewickley, PA (US); Toygun Cetinkaya, Pittsburgh, PA (US)

(21) Appl. No.: 18/848,255

(22) PCT Filed: Mar. 17, 2023
(86) PCT No.: PCT/US2023/015519

§ 371 Date: Sep. 18, 2024

Related U.S. Application Data
(60) Provisional application No. 63/321,425, filed on Mar. 18, 2022.

(51) Int. Cl. H05K 3/10; B22F 1/05; B22F 3/16; B28B 1/20; B28B 7/36; C04B 41/00; H05K 3/40

(52) U.S. Cl. CPC H05K 3/101; B22F 1/05; B22F 3/16; B28B 1/20; B28B 7/36; C04B 41/0072; H05K 3/4007; B22F 2301/15; B22F 2301/205; B22F 2301/35; B22F 2304/05; B22F 2304/10; B22F 2998/10; C04B 2235/5436; C04B 2235/5445; C04B 2235/5454; C04B 2235/602; C04B 2235/94

(57) ABSTRACT

A method for manufacturing a structure having at least one microscale feature includes mixing a powdered material with a binder to yield a slurry, shaping the slurry to yield a green device, and sintering the green device to yield the structure.

### CROSS REFERENCE TO RELATED APPLICATIONS

This application claims priority to U.S. Provisional Application No. 63/321,425 filed Mar. 18, 2022, the disclosure of which is hereby incorporated by reference in its entirety.

### BACKGROUND OF THE INVENTION

Microdevices are utilized in a broad range of fields, including mechanical and electromechanical systems, consumer products, brain-machine interfaces, biomolecule sensing systems, and implantable devices, to name a few. Various microfabrication techniques are currently used for manufacturing microdevices, including micromilling, etching and lithography, electrochemical micromachining, micro electro-discharge machining (μEDM), and 3D printing. However, none of the existing processes are able to provide the combination of high-throughput, precision, and low cost demanded by many three-dimensional microscale devices made from metals and ceramics. Particularly, effective and accurate methods for making metallic and ceramic devices that demand high precision and specific features, e.g., sharp edges, high aspect ratios, small dimensions, and array formations, are lacking. Furthermore, some of these devices may be solid whereas other require specific porosity distribution. These requirements bring serious limitations in the use of metallic and ceramic microdevices and hinder advances in many fields.

One way to create microdevices in a scalable fashion is to use injection molding. The injection molding process is commonly used for miniature to macro-scale devices made from various thermopolymers. However, metal- and ceramic-injection molding processes has also been demonstrated for different, macro-scale parts. However, injection molding has serious limitations in creating micro-scale features: even for polymers, special provisions such as very expensive molding equipment, vacuum molding systems, specialized and costly molds, and ejection features are needed to successfully create micro-scale features. Another drawback to injection molding includes the production of scrap, which is costly due to the high costs of materials used for microdevice applications and time wasted generating scrap material. Additional drawbacks include the inability to control material properties on a microscale, such as porosity, and the inability to form complex geometries and control feature resolution. Metal- and ceramic-injection molding for micro-scale features bring significantly more challenges in all aspects, and, thus, has not been utilized commercially.

One option for scalable (or high-throughput) production of microdevices is via micro powder injection molding (μPIM). However, this method faces several drawbacks, such as the adhesion between green-state micro-components. It is common for the hard mold to damage the component's microstructure during demolding. The molds used in injection molding are very expensive and the mold life is concise due to the abrasive nature of the metal-based slurry. Thus, it is impractical to make hundreds of molds even for high production run products. Micro-scale features with high aspect ratios, sharp tips, and other complex geometries cannot be made via this technique. Thus, the fabrication of high precision microdevices for the mass production of different applications is not currently achievable.

Accordingly, those skilled in the art continue with research and development efforts in the field of fabricating metallic microdevices.

### SUMMARY OF THE INVENTION

Disclosed is a method for manufacturing a microdevice from metals, ceramics, or a combination thereof.

The disclosed method enables fabricating complex and micro-scale geometries and controlling the microstructure, including porosity and material distribution.

In one example, the method includes mixing a powdered material with a binder to yield a slurry, shaping the slurry using low-cost molding using the spin-casting process with soft molds to yield a green device, and sintering the green device to yield the final microdevice.

In another example, the method includes creating a master mold fabricating a production mold with the master mold, mixing a powdered material with a binder to yield a slurry, pouring the slurry into the production mold, shaping the slurry in the production mold to yield a green device, subjecting the green device to a temperature of up to 200° C. for a predetermined period of time, and sintering the green device to yield the microdevice.

Other non-limiting embodiments or aspects are set forth in the following illustrative and exemplary numbered clauses:
Clause 1. A method for manufacturing miniature and micro devices having at least one microscale feature, the method comprising: mixing powdered material with a binder to yield a slurry; shaping the slurry to yield a green device; sintering the green device to yield the structure.
Clause 2. The method of claim 1, wherein the shaping comprises loading the slurry into a mold and spin-casting the slurry to obtain the green device.
Clause 3. The method of claim 1, wherein the shaping comprises compressing the slurry into a mold.
Clause 4. The method of any one of claims 1-3, wherein the binder comprises one or more solvent and one or more polymer.
Clause 5. The method of claim 4, further comprising subjecting the green device to a predetermined temperature for a predetermined period of time effective to evaporate the solvent.
Clause The method of any one of claims 1-5, wherein the powdered material has an average particle size of about 1 nm to about 50 μm.
Clause 7. The method of any one of claims 1-6, wherein the powdered material comprises one or more metals.
Clause 8. The method of any one of claims 1-7, wherein the powdered material comprises one or more ceramics.
Clause 9. The method of any one of claims 1-8, wherein the powdered material comprises one or more polymers.
Clause 10. The method of any one of claims 1-8, wherein the powdered material comprises a combination of metals and ceramics.
Clause 11. The method of any one of claims 1-10, wherein different parts of the green device have different compositions of the powdered material.
Clause 12. The method of any one of claims 1-11, wherein the powdered material comprises one or more nickel, stainless steel, and titanium alloy.
Clause 13. The method of any claims 1-12, wherein the binder comprises one or more polyvinyl alcohol, polyethylene glycol, polyethylene, polypropylene, camphene, and synthetic or natural wax and stearic acid.
Clause 14. The method of any one of claims 1-13, wherein the predetermined period of time is about 5 minutes to about 48 hours.
Clause 15. The method of any one of claims 1-14, wherein the structure comprises a plurality of microscale features.
Clause 16. The method of any one of claims 1-15, wherein the structure is a micropillar array having a plurality of pillars with a height of about 10 μm to about 5000 μm.
Clause 17. The method of any one of claims 1-16, wherein the structure is a micropillar array having a plurality of pillars with a diameter of about 25 μm to about 1000 μm.
Clause 18. The method of any one of claims 16-17, wherein each pillar of the plurality of pillars includes a through-hole passing through a central axis of each pillar along their height dimension and having a diameter of about 50 μm to about 900 μm.
Clause 19. The method of any one of claims 1-18, wherein the structure comprises an array of microelectrodes with individually addressable microelectrodes.
Clause 20. The method of any one of claims 1-19, wherein the structure comprises an array of microelectrodes with electrical interconnects.
Clause 21. The method of any one of claims 1-20, further comprising pouring the slurry into a mold.
Clause 22. The method of claim 21, further comprising removing the green device 210 from the mold.
Clause 23. A method for manufacturing a structure having at least one microscale feature, the method comprising: creating a master mold; fabricating a production mold with the master mold; mixing a powdered material with a binder to yield a slurry; pouring the slurry into the production mold; shaping the slurry in the production mold to yield a green device; and sintering the green device to yield the structure.
Clause 24. The method of claim 23, further comprising removing the green device from the production mold.
Clause 25. The method of claim 23, further comprising removing the green device from the production mold using centrifugation.
Clause 26. The method of any one of claims 23-25, wherein the binder comprises a solvent.
Clause 27. The method of claim 26, further comprising subjecting the green device to a predetermined temperature for a predetermined period of time effective to evaporate the solvent.
Clause 28. The method of any one of claims 23-27, wherein the master mold comprises an acrylic material.
Clause 29. The method of any one of claims 23-27, wherein the master mold comprises a metal material.
Clause 30. The method of any one of claims 23-27, wherein the master mold comprises a resin, thermoplastic, or thermoset material.
Clause 31. The method of any one of claims 23-30, wherein the master mold is fabricated using mechanical micromachining.
Clause 32. The method of any one of claims 23-31, wherein the master mold is fabricated from another master mold using molding.
Clause 33. The method of any one of claims 23-32, wherein the master mold is coated with a demolding chemical such as by silinazing.
Clause 34. The method of any one of claims 23-33, wherein the production mold comprises an elastomer.
Clause 35. The method of any one of claims 23-34, wherein the production mold comprises a hard plastic coated with one or more of a soft elastomer and a surface coating for easier demolding.
Clause 36. The method of any one of claims 23-35, wherein the fabrication mold is coated with a demolding chemical such as by silinazing.
Clause 37. The method of any one of claims 23-36, wherein the shaping comprises compressing the slurry into the production mold.
Clause 38. The method of any one of claims 23-37, wherein the shaping loading the slurry into the production mold and spin-casting the slurry to obtain the green device.
Clause 39. The method of any one of claims 23-38, wherein the powdered material has an average particle size of about 10 nm to about 50 μm.
Clause 40. The method of any one of claims 23-39, wherein the powdered material comprises one or more metals.
Clause 41. The method of any one of claims 23-40, wherein the powdered material comprises one or more ceramics.
Clause 42. The method of any one of claims 23-41, wherein the powdered material comprises one or more polymers.
Clause 43. The method of any one of claims 23-42, wherein the powdered material comprises a combination of metals and ceramics.
Clause 44. The method of any one of claims 23-43, wherein different parts of the green device have different compositions of the powdered material.
Clause 45. The method of any one of claims 23-44, wherein the powdered material comprises one or more of nickel, stainless steel, and titanium alloy.
Clause 46. The method of any one of claims 23-45, wherein the binder comprises one or more of polyvinyl alcohol, polyethylene glycol, polyethylene, polypropylene, and synthetic or natural wax and stearic acid.
Clause 47. The method of any one of claims 23-46, wherein the predetermined period of time is about 5 minutes to about 48 hours.
Clause 48. The method of any one of claims 23-47, wherein the structure comprises a plurality of microscale features.
Clause 49. The method of any one of claims 23-48, wherein the structure is a micropillar array having a plurality of pillars with a height of about 1 μm to about 5000 μm.
Clause 50. The method of any one of claims 23-49, wherein the structure is a micropillar array having a plurality of pillars with a diameter of about 25 μm to about 1000 μm.
Clause 51. The method of any one of claims 45-50, wherein each pillar of the plurality of pillars includes a through-hole passing through a central axis of the pillars along their height dimension and having a diameter of about 50 μm to about 900 μm.
Clause 52. The method of any one of claims 23-51, wherein the structure comprises an array of microelectrodes with individually addressable microelectrodes.
Clause 53. The method of any one of claims 23-52, wherein the structure comprises an array of microelectrodes with electrical interconnects.

### BRIEF DESCRIPTION OF THE DRAWINGS

The above-mentioned and other features and advantages of this disclosure, and the manner of attaining them, will become more apparent and the disclosure itself will be better understood by reference to the following descriptions of embodiments of the disclosure taken in conjunction with the accompanying drawings, wherein:

FIG. 1 is a flow chart of a method for manufacturing a microdevice;

FIG. 2 is an image of a microdevice manufactured by the method of FIG. 1;

FIG. 3A is an image of a portion of microdevice manufactured by the method of FIG. 1;

FIG. 3B is a cross-sectional view of a portion of the image of FIG. 3A;

FIG. 4 is an image of a portion of microdevice manufactured by the method of FIG. 1;

FIG. 5A is a scanning electron micrograph of a portion of microdevice manufactured by the method of FIG. 1;

FIG. 5B is a scanning electron micrograph of a portion of microdevice manufactured by the method of FIG. 1;

FIG. 5C is a scanning electron micrograph of a portion of microdevice manufactured by the method of FIG. 1;

FIG. 5D is a scanning electron micrograph of a portion of microdevice manufactured by the method of FIG. 1;

FIG. 6 is a flow diagram of a method for manufacturing a microdevice;

FIG. 7 is a perspective view of a microdevice manufactured by the method of FIG. 6 and mold of for manufacturing the microdevice; and

FIG. 8 is an exploded CAD model of an assembly of a portion of a circuit board manufactured by the method of FIG. 6.

The exemplifications set out herein illustrate exemplary embodiments of the disclosure, and such exemplifications are not to be construed as limiting the scope of the disclosure in any manner.

### DETAILED DESCRIPTION OF THE INVENTION

All numbers used in the specification and claims are to be understood as being modified in all instances by the term “about”. By “about” is meant a range of plus or minus ten percent of the stated value. As used in the specification and the claims, the singular form of “a”, “an”, and “the” include plural referents unless the context clearly dictates otherwise. The terms “first”, “second”, and the like are not intended to refer to any particular order or chronology, but instead refer to different conditions, properties, or elements. By “at least” is meant “greater than or equal to”.

Although the invention has been described in detail for the purpose of illustration based on what is currently considered to be the most practical and preferred embodiments, it is to be understood that such detail is solely for that purpose and that the invention is not limited to the disclosed embodiments, but, on the contrary, is intended to cover modifications and equivalent arrangements that are within the spirit and scope of the appended claims. For example, it is to be understood that the present invention contemplates that, to the extent possible, one or more features of any embodiment can be combined with one or more features of any other embodiment.

The disclosure allows for a scalable, high-precision, and low-cost manufacturing process for the fabrication of metallic microdevices. The disclosure may utilize a powder-metallurgy approach wherein a powdered metal is first mixed with a binder. The binder material may include a blend of polymers and waxes, and is sacrificial. The resulting thick “slurry” may then be loaded into production molds. Specifically, the disclosed two-step molding process advantageously enables manufacturing of high-aspect-ratio, sharp structures, and arrays of structures. In one example, the production molds are “soft,” and easily cleanable. Another advantage to the disclosure is that the processes do not require significant investment and development needed in injection micro-molding processes.

The disclosure may utilize a two-step mold fabrication approach. For example, a hard master mold can be used to create soft production molds. The soft production molds can then be used to manufacture microdevices, such as electrodes and microarrays, as shown and described herein.

The disclosure includes methodology for scalable, high-precision, and low-cost manufacturing processed for fabrication of structures, interchangeably referred to as microdevices, including, but not limited to, microelectrode arrays, microneedle arrays, and other microscale devices. The disclosure includes processes including using a powdered material, such as in a powder-metallurgy approach, such that a powdered material is mixed with a binder to yield a slurry. The disclosure also includes centrifuge-molding (spin-casting) processes for the slurry. In other aspects, the disclosure includes molding performed by direct compression of the slurry into a mold. In yet another aspect, the disclosed methodology enables the ability to control the porosity of the final structure, or microdevice by selecting powder-size and binder/powder ratios, allowing for a fully dense to a more porous structure based upon the intended application.

Further, as disclosed herein, there are many advantages to the disclosed method 100. In one aspect, the disclosed method 100 enables fabrication of structures, or microdevices 200, from typically difficult-to-machine metals and metal alloys. While mechanical micromachining processes (e.g., micromilling) are traditionally used for creating micro-scale parts on metals and polymers, materials having high mechanical strength and hardness result in high cutting forces, excessive tool wear, and damage to workpieces. Using the disclosed method 100 with soft micro-molding techniques eliminates the above-mentioned drawbacks to micromilling. Further, the disclosed method 100 allows for fabrication of microdevices 200 from multiple metals, as either alloys or mixtures. Further, in addition to uniform mixtures, metallic materials may be varied at different locations on the structure or microdevice 200, e.g., an array of pillars from one material may be connected to a backing made from a different material. This can be achieved during the same process simultaneously.

Examples of structures, or microdevices 200, that may be manufactured by the disclosed method 100 include microelectrode arrays could be used in biosensors, fuel cells, or battery applications, neural probe applications, implantable electro-sensor applications, sample collections using an array of porous devices (absorption of bodily fluids), metal microneedle arrays used in the biomedical field, micro-featured geometries used in mems devices, micro gears, micro actuators, micro semi-circular, semi-spherical geometries, and 3D spline surfaces. This list of examples is non-exclusive, and it is contemplated that any geometry on the micrometer scale may be manufactured by the method 100 disclosed herein. The method 100 allows for the manufacturing structures having a wide range of intricate shapes, including knobs, knurls, gears, splines, and more. This flexibility makes this method 100 suitable for a wide range of applications.

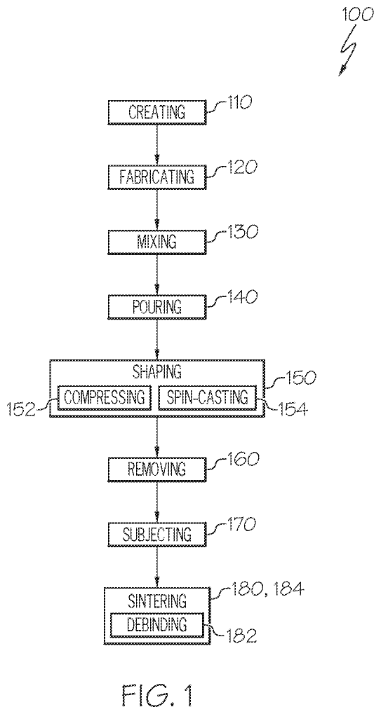

Referring to FIG. 1, disclosed is a method 100 for manufacturing a structure, interchangeably referred to as a microdevice 200. A microdevice 200 is defined herein as a structure (part) generally having dimensions within 10 μm to 200 mm, although it is understood that the structure may be larger, and with specific features as small as 10 μm, referred to herein as microfeatures 232. The microdevice 200 may be further characterized as any structure having at least one microfeature 230. In one example, the microdevice 200 has a height of about 10 μm to about 10 mm. The microdevice 200 may further be characterized by aspect ratio, meaning the ratio of its longest dimension to its shortest dimension, such as ratio of height to width. In one example, the microscale features of the microdevice 200 may have an aspect ratio of 0.1 to 50.

Still referring to FIG. 1, the method 100 includes mixing 130 a powdered material with a binder to yield a slurry. The powdered material may be any material that is available in a powder form and that is sinterable. For example, the powdered material may be a metal, such as nickel or stainless steel, and more specifically nickel powder—APS 3 to 7 μm—99.9% purity, stainless steel 316L powder—Purity of 99.9%, APS 5 μm, or Stainless Steel 430L Powder—Purity of 99.9%, APS 5 μm. In another example, the powdered material may be a ceramic, such as silica, zirconia, alumina, or silicon nitride. In yet another example, the powdered material may be a polymer, such as a thermoplastic material, and even more specifically such as PEEK or UHDPE. In one example, the powdered material has an average particle size of about 10 nm to about 50 μm.

The disclosed method 100 advantageously allows for a microdevice 200 to be comprised of more than one material. Importantly, the disclosed method 100 may be used to create multi-material structures (e.g., one or more of a metal and ceramic material) by either mixing the two or more materials uniformly, functionally grading the two or more materials, or having one portion from one material, such as a ceramic, and another portion from another material, such as a metal, with a strong adhesion between the two portions of the structure. The disclosed method 100 allows for combining different materials to form the microdevice 200 with different materials having comparable sintering parameters.

The binder may be a polymeric material, such as a PVA powder, such as 87% hydrolyzed, MW 100,000. In another example, the binder includes one or more of PVA, polyethylene glycol, polyethylene, polypropylene, or a synthetic or natural wax and stearic acid. May be organic or inorganic, such as complex carbohydrates, including, for example, gums or polysaccharides. It is understood that the molecular weight (MW) of polymeric materials refers to weight-averaged molecular weight (Mw) unless otherwise indicated.

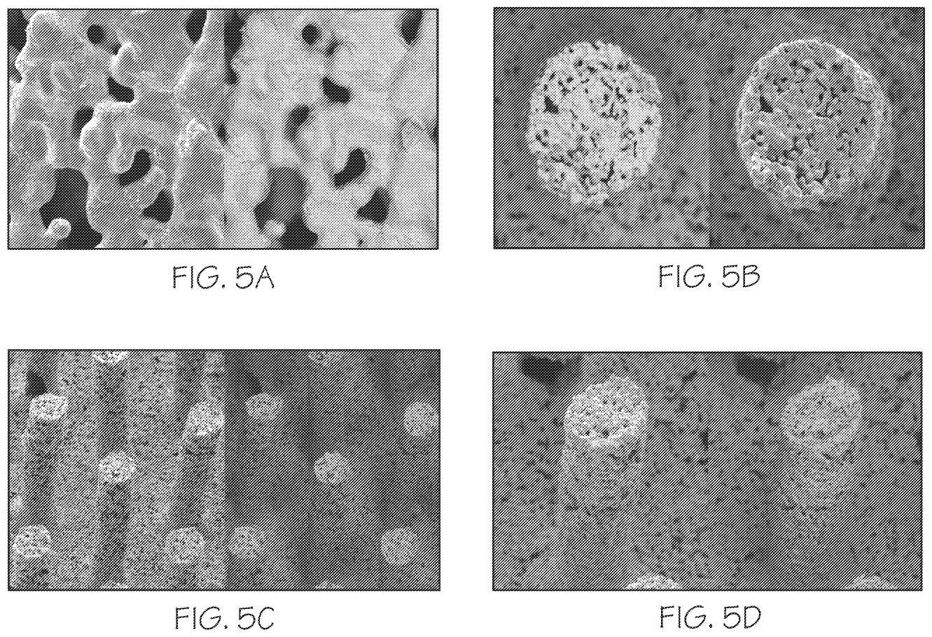

In one example, the slurry is prepared by mixing a metal powder, a binder, a dispersant, and a surfactant. A wide range of material combinations can be used to prepare this mixture. The combination of these materials can be adjusted according to the desired final properties and necessary operational needs. The size of the metal particles used with this method can be micro- or nano-sized particles, or a combination of both. Choosing a specific proportion of micro- and nano-sized powders, along with the sintering parameters, is the primary means to control the porosity of the final structure, or microdevices 200. Various particle sizes can be selected to increase the final product's density or decrease the surface roughness of micro-features. Different metal particles can be mixed for desired properties or to form metal alloys. Similarly, metal and ceramic particles may also be mixed to obtain, e.g., a conductive ceramic-metal system. Advantageously, the compositions of the microdevices 200 can be accurately controlled by adjusting the components of the slurry. In one non-limiting example, a nickel powder (3-7 μm particle size) and polyvinyl alcohol (PVA) are mixed. Depending on the type of metal (e.g., nickel, titanium, etc.), powder size (e.g., D₅₀=2 μm), and sintering properties, microdevices 200 ranging from full-density to high porosity may be obtained. If compatible metals are used, multiple metals and multiple different powder sizes (of the same and different metals) may be considered. Further, nano-scale powders and sintering aids may be added to the slurry to control the final density/porosity. The initial concentration of slurry (metal-to-binder ratio) and binder type are important parameters in obtaining precise microdevices 200. FIGS. 5A-5D are scanning electron micrographs showing porosity and density achieved by the disclosed method 100. As shown in those micrographs, porosity is controllable by using the disclosed method 100.

The mixing 130 may be done under any conditions necessary for the given materials. In one example, the mixing 130 includes the following ratios in (w/w): 50% to 90 wt. % of powdered material, 3% to 20% a binder, and 5% to 50% water. The mixing may be done at elevated temperatures: for example, the mixing temperature may be about 60° C. to about 100° C. After the mixing 130, the method 100 may include pouring 140 the slurry into a mold.

Still referring to FIG. 1. The method 100 includes shaping 150 the slurry to yield a “green” device 210. The word “green” here refers to the unsintered sample, which may or may not include the binder. In one example, the shaping 150 includes compressing 152 the slurry into a mold, such as a production mold 250. In another example, the shaping 150 includes spin-casting 154, or centrifuge-molding, the slurry in a mold or production mold 250. In one non-limiting example, the shaping 150 includes spin-casting 154 the slurry while in a mold via the following parameters: temperature: 10-40° C., pressure: atmospheric pressure, time: 5-200 mins, and humidity: 5%-60%. In this example, the spin-casting process can evaporate the solvent (water) in the slurry to obtain a solid green sample.

It is understood that spin-casting 154 includes spin-casting 154 onto a polymer mold, and, more particularly, on a soft polymer mold. This approach allows for scalability at a low cost as compared to traditional molding techniques that require expensive molds.

After the shaping 150, the method 100 may include removing 160 the green device 210 from the mold. The removing 160 or demolding process can be done manually or via the help of a robotic or passive demolding system. In another example, the centrifuge is used for removing 160 or demolding the green device 210 from the soft mold.

In one non-limiting example, a mold loaded with the slurry may be placed in a centrifuge and centrifuged for a period of time at a given speed/G-force. After spin-casting inside a centrifuge for a predetermined period of time and removing any excess material, such as solvents used in the binder, the metal slurry may be dried, and the green device 210 may be demolded from the production mold 250. The mixture of slurry should be arranged so that the green device 210 can withstand handling and demolding without damaging or distorting the geometry of the green device 210.

Still referring to FIG. 1, the method 100 may include subjecting 170 the green device 210 to a predetermined temperature for a predetermined period of time for evaporating any solvent from the binder. In one example, the predetermined temperature is from room temperature up to 400° C. In another example, the predetermined temperature is from room temperature up to 200° C. The predetermined time may be any amount of time necessary to evaporate solvent from the binder. In one example, the subjecting 170 occurs for a predetermined period of about 30 minutes, or, alternatively, at room temperature for about 24 hours at atmospheric pressure.

Still referring to FIG. 1, the method 100 includes sintering 180 the green device 210 to yield the microdevice 200. The sintering 180 may include two steps. In one example, the sintering 180 includes an initial step of thermal debinding 182, i.e., to remove the polymer binder. In the thermal debinding 182 step, the binder is removed from the green device 210. This debinding 182 process may include a chemical and/or thermal approach and may not be required depending on the binder constituents, i.e., for example, if the binder constituents evaporate at room temperature or if the binder can be “burned off” during the sintering process. A specific thermal profile is then used to sinter the structures. In one example, the debinding 182 is performed under the following conditions: exposure to a temperature range of 450-650° C. at an average rate of 5° C./min (range: 1-10° C./min), atmospheric pressure, in the presence of argon gas, for a time period of about 30-120 mins.

The sintering 180 may further include a second sintering step 184 under the following conditions: exposure to a temperature range of 200-2200° C. at an average rate of 5° C./min (range: 1-10° C./min), atmospheric pressure, in the presence of argon gas, for a time period of about 30-180 mins. After sintering 180, the microdevice 200 may naturally cool to room temperature.

Sintering 180 is utilized to obtain the final microdevice 200. This process enables the slurry to maintain the shape of the mold. Inclusion of a solvent, such as water, alcohol, acetone, etc., may be utilized either during the centrifugation or with subsequent processing (such as exposure to vacuum, and heat), the solvent can then be evaporated, resulting in the mixture of metal powder and binder phase with sufficient strength, such that they can be removed from the molds without damaging the structures. In another example, a light, chemical, or low-temperature curable binder can be used, and the green device 210 may be exposed to such treatment to obtain the hardened powder/binder mixture to yield a desired microdevice 200.

It is understood that the green devices 210 experience a relatively significant level of shrinkage during sintering 180, e.g., about 20%. However, the shrinkage is well-controlled and reproducible. The shrinkage is dependent on the initial slurry concentration. Accordingly, the sintering temperature profile is selected to prevent non-uniform shrinkage and crack formation. Furthermore, the sintering environment is selectively controlled to prevent oxidation or other adverse chemical effects on the fabricated microdevices 200.

As stated above, the disclosed method 100 may be used to fabricate a variety of microdevices 200. The microdevice 200 manufactured by the method 100 disclosed herein may include one or more microscale feature 230. The microscale feature 230 may be any non-planar feature of the microdevice 200, such as a generally columnar feature, a plurality of microscale features 232, a shape having a curvature, a pointed structure such as a microneedle, a gear tooth, or any other geometry needed for the intended application.

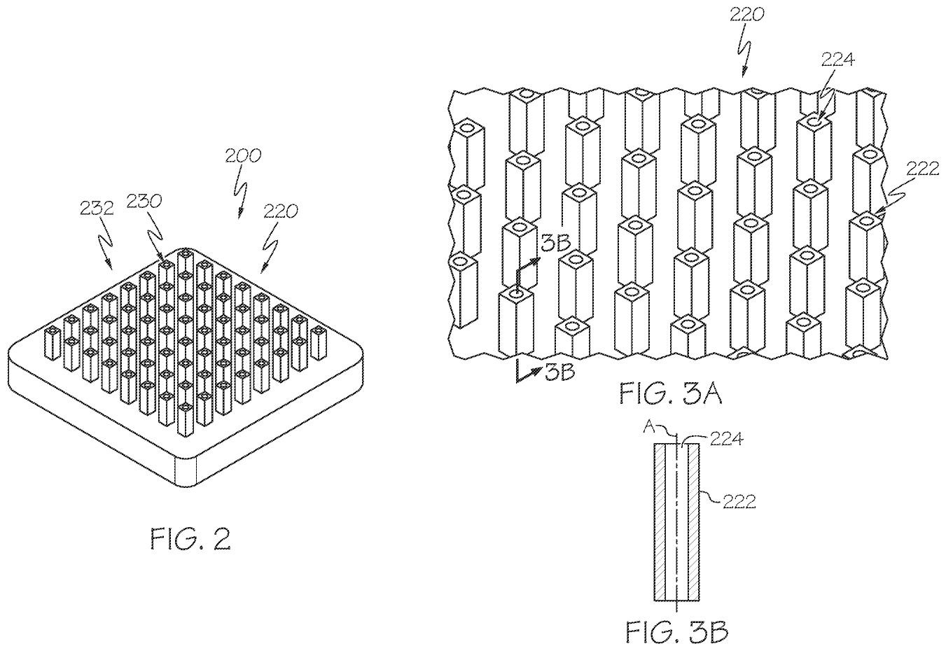

In yet another example, the microdevice 200 is a microelectrode. In another example, the microdevice 200 is a micropillar array. The micropillar array may have a plurality of microscale features 232, such as a plurality of pillars 220. The plurality of pillars 220 may have a height of about 10 μm to about 5000 μm. The pillars may have circular, square or other cross-sectional geometry, as shown in FIGS. 3A and 3B. The width of the pillars may range from 50 μm to 1000 μm. In one non-limiting example, the plurality of pillars 220 have a height of about 100 μm to about 300 μm. In yet another example, the plurality of pillars 220 have a height of about 150 μm to about 250 μm. Each pillar 222 of the plurality of pillars 220 may include a through-hole 224 passing through a central axis A of each pillar along their height dimension having a diameter of about 50 μm to about 900 μm, as shown in FIG. 2, FIGS. 3A, and 3B. In one example, the diameter of the hole is about 100 μm to 150 μm.

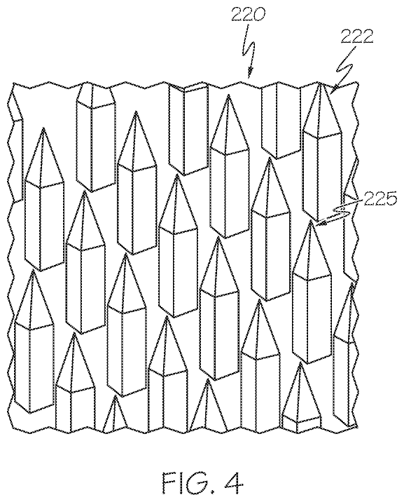

In another example, each pillar 222 of the plurality of pillars 220 includes angles forming a point 226 as shown in FIG. 4. The angles may be of any degree necessary for the intended application. In one example, the angles are about 10° to about 50°. In another example, the angles are about 30°.

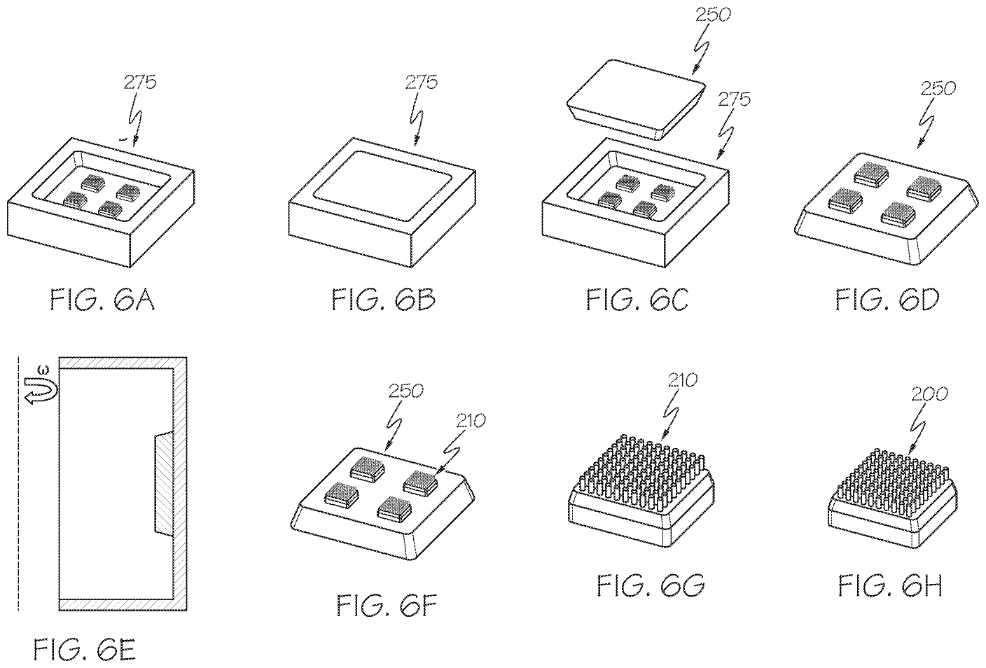

In one or more examples, the method 100 may be used to manufacture a set of microelectrode (micropillar) arrays that can be used for electrochemical detection of biological and chemical agents. A set of exemplary micropillar arrays are depicted in FIG. 6. The microelectrochemical detection system (μEDS) offers high-density integration, high sensitivity, fast analysis time, and reduced reagent consumption. The miniaturized working electrode is typically the core component of the μEDS because it characteristic directly determines the system's performance. When compared to microelectrodes having conventional shapes such as a band, ring, and disk, the three-dimensional (3D) micropillar array electrode offers significant potential in improving the current response and decreasing the limits of detection due to its much larger reaction area.

In another example, the method 100 may be used to manufacture microdevices 200 having electrodes or electrode arrays for implantation into human or animal body. For example, such electrodes may be used for brain or nervous system stimulation or measuring action potentials. In another example, the electrodes are used for peripheral nervous (e.g., vagus nerve) stimulation for alleviating neurological disorders (e.g., Parkinson's) or supporting other brain functions.

As shown in FIG. 6, a master mold 275 includes the microfeatures of the micropillar array microdevice 200. A polymer is then cured on the master mold 275 to form a production mold 250. The production mold 250 may then be demolded from the master mold 275. After demolding, the production mold 250 may be filled with a powder and binder slurry as described herein. The filled production mold 250 may then be centrifuged to shape the slurry into one or more green device 210. The green device 210 may then be subjected to an elevated temperature to remove the binder from the green device 210. After drying, the green device 210 may be sintered to yield the micropillar array microdevice 200.

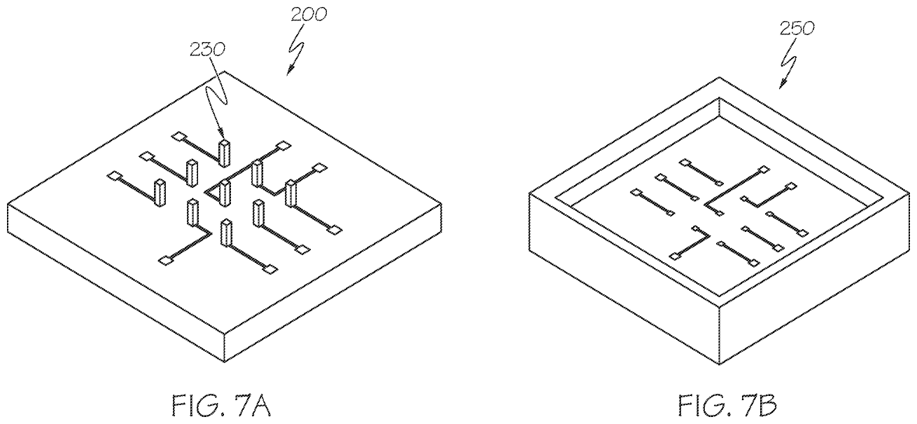

Many micro-featured designs and microscale features 232 can be fabricated with the disclosed methodology, and one advantage to the disclosure is the capability of making individually addressable electrodes, see FIG. 7. These types of electrodes can be used in many biomedical and MEMS applications. Micropillar array electrodes have been widely applied in electrochemical detection owing to their advantages of increased mass transport, lower detection limit, and the potential to be miniaturized. With the disclosed methodology, high production rates can be achieved for microelectrochemical detection systems. Some of these applications demand solid (nearly non-porous) electrodes, whereas others require porous electrodes with desired porosity: the disclosed method is capable of creating such devices with controllable shapes, dimensions, and porosity.

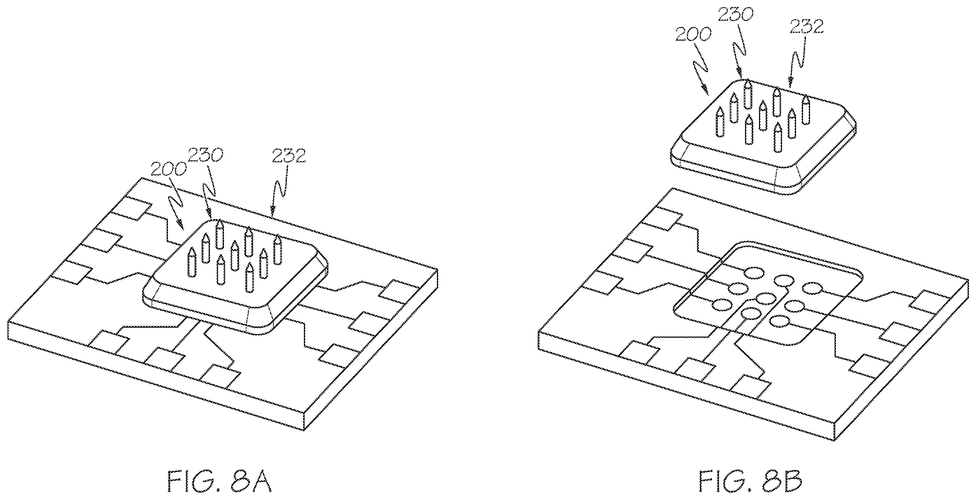

In another example, the microdevice 200 includes micro needle arrays that are individually accessible through a co-sintered insulating block. An example CAD model is shown in FIG. 8. These insulating blocks can be made from either ceramics or metal fillers that are compatible with the sintering parameters of the conductive powdered material used for making the pillar/needle arrays via the method 100.

Referring to FIG. 6, and in accordance with the above-mentioned methodology, the method 100 for manufacturing a microdevice 200 may be defined by the following steps. The method 100 may include creating 110 a master mold 275 having the same geometry as the microdevice 200. In one example, the master mold 275 comprises an acrylic material. In another example, the master mold 275 comprises a metal or a resin. The master mold 275 may be manufactured using various techniques including mechanical micromachining, diamond micromilling, molding, spin-casting, 3D micro printing, and 3D nano-printing.

In one or more examples, the positive master mold 275 may be fabricated using a mechanical micromachining process with micro-scale (as small as 10 μm in diameter) milling tools within a high-precision computer-controlled miniature machine tool system with the motion accuracy of 1 μm. An example of the fabrication of a master mold 275 is described as follows. The master mold 275 material does not have to be metal and can be a hard polymer (e.g., acrylic) or resin. The master mold 275 may be mechanically micromachined out of a rigid polymer or metal. The master mold 275 material may be any easily machinable material, including metals (e.g., aluminum, brass) or hard plastics, allowing a wide range of geometries. In alternative examples, the master mold 275 fabrication may include lithography or micro electrode-discharge machining to make the molds from various materials, including plastics, ceramics, or metals (including stainless steel, aluminum, copper, iron, tungsten, and their alloys.) Optional surface treatments can be applied to the master mold 275 to attain lower surface roughness and easier demolding.

The method 100 may further include fabricating 120 a production mold 250 with the master mold 275. In one example, the production mold 250 comprises silicone. In another example, the production mold is a resin or other harder polymer, which may be coated by a softer polymer such as parylene-C to assist demolding. Plasma cleaning and silanization may also be used to enable easier demolding. The master mold 275 may be used to 100s to 1000s of production molds 250 without degredation. In one example, the production molds 250 are made from a soft polymer, such as silicone, polyurethanes, thermoplastic, or thermoset rubber. In one non-limiting example, the production mold 250 is comprised of polydimethylsiloxane (PDMS), which exhibits exceptional net-shape replicating properties. Other elastomers, soft resins, or any material with sufficiently low surface energy can be used to allow easy demolding. A large number of soft molds (100 to 1000+) can be fabricated from the master mold 275 to accommodate high production rates. Unlike metal injection molding, one advantage of the disclosed method 100 is that the production molds 250 produced are very low cost and easily scalable.

The softness and elasticity of the production molds 250 also allow the demolding of green devices 210 or molded pieces without damage. In one example, the fabricating 120 may be defined as micromolding to create production molds 250 from the master molds 275.

The method 100 further includes mixing 130 a powdered material with a binder to yield a slurry, pouring 140 the slurry into the production mold 250, shaping 150 the slurry in the production mold 250 to yield a green device 210, subjecting 170 the green device 210 to a temperature of up to 200° C. for a predetermined period of time to evaporate the solvent fully, and sintering 180 the green device 210 to yield the microdevice 200.

In one example, the shaping 150 includes compressing 152 the slurry into the production. In another example, the shaping 150 includes spin-casting 154 the slurry in the production mold 250. The method 100 may further include removing 160 the green device 210 from the production mold 250 after the shaping 150.

As disclosed herein, the method 100 is advantageous in that it allows for controllable manufacturing of structures on a micrometer scale. In one aspect, the method 100 allows for improved material efficiency. The disclosed high-temperature powder processing uses 100% of the powdered material, producing significantly less waste than other machining processes. The method 100 can accommodate a wide range of intricate shapes, making this method 100 suitable for a range of applications. Further, the method 100 yields desirable material properties. For example, sintered stainless steel offers a wide range of advantageous mechanical and physical properties, including controlled level of porosity. Additional alloying elements can also be added to improve certain qualities further. For example, ferromagnetism may be utilized if magnetic stainless steel powder is used. Further, porosity is controllable by selecting powder size, using bimodal powder mixing, and selectively controlling sintering time. The method 100 further allows for reduced assemblies needed during manufacturing. By consolidating multiple parts and assembly steps into a single powdered metal component, sintering minimizes manufacturing steps, lowering costs. The use of lower-cost molding system (the spin casting approach) and highly reproducible and low-cost molds (e.g., the elastomer molds), the system enables high-throughput production of devices with micro scale features at a very low cost.

Although various examples of the method 100 and microdevice 200 have been shown and described, modifications may occur to those skilled in the art upon reading the specification. The present application includes such modifications and is limited only by the scope of the claims.

1. A method for manufacturing a structure having at least one microscale feature, the method comprising:
mixing powdered material with a binder to yield a slurry, wherein the powdered material comprises one or more metals;
shaping the slurry to yield a green device; and
sintering the green device to yield the structure,
wherein the shaping comprises loading the slurry into a mold and spin-casting the slurry to obtain the green device.

2.-3. (canceled)

4. The method of claim 1, wherein the binder comprises one or more solvent and one or more polymer.

5. The method of claim 4, further comprising subjecting the green device to a predetermined temperature for a predetermined period of time effective to evaporate the solvent.

6. The method of claim 1, wherein the powdered material has an average particle size of about 1 nm to about 50 μm.

7.-9. (canceled)

10. The method of claim 1, wherein the powdered material further comprises one or more ceramics.

11. The method of claim 1, wherein different parts of the green device have different compositions of the powdered material.

12. The method of claim 1, wherein the powdered material comprises one or more of nickel, stainless steel, and titanium alloy.

13.-15. (canceled)

16. The method of claim 1, wherein the structure is a micropillar array having a plurality of pillars with a height of about 10 μm to about 5000 μm.

17. (canceled)

18. The method claim 16, wherein each pillar of the plurality of pillars comprises a through-hole passing through a central axis of each pillar along their height dimension and having a diameter of about 50 μm to about 900 μm.

19. The method of claim 1, wherein the structure comprises an array of microelectrodes with individually addressable microelectrodes, an array of microelectrodes with electrical interconnects, or combinations thereof.

20.-22. (canceled)

23. A method for manufacturing a structure having at least one microscale feature, the method comprising:
creating a master mold;
fabricating a production mold with the master mold;
mixing a powdered material with a binder to yield a slurry, wherein the powdered material comprises one or more metals;
pouring the slurry into the production mold;
shaping the slurry in the production mold to yield a green device, wherein the shaping comprises loading the slurry into the production mold and spin-casting the slurry to obtain the green device; and
sintering the green device to yield the structure.

24. (canceled)

25. The method of claim 23, further comprising removing the green device from the production mold using centrifugation.

26.-27. (canceled)

28. The method of claim 23, wherein the master mold comprises an acrylic material, a metal material, a resin material, a thermoplastic material, or a thermoset material.

29.-30.

31. The method of claim 23, wherein the master mold is fabricated using mechanical micromachining, fabricated from another master mold using molding, or combination thereof.

32.-33. (canceled)

34. The method of claim 23, wherein the production mold comprises an elastomer or a hard plastic coated with one or more of a soft elastomer and a surface coating for easier demolding.

35. (canceled)

36. The method of claim 23, wherein the production mold is coated with a demolding chemical such as by silinazing.

37.-38. (canceled)

39. The method of claim 23, wherein the powdered material has an average particle size of about 10 nm to about 50 μm.

40.-42. (canceled)

43. The method of claim 23, wherein the powdered material further comprises one or more ceramics.

44. (canceled)

45. The method of claim 23, wherein the powdered material comprises one or more of nickel, stainless steel, and titanium alloy.

46.-47. (canceled)

48. The method of claim 23, wherein the structure comprises a plurality of microscale features.

49.-53. (canceled)
